(19) United States
(12) Patent Application Publication
(10) Pub. No.: US 2024/0162317 A1
(43) Pub. Date: May 16, 2024

(54) NON-VOLATILE MEMORY DEVICE AND METHOD FOR MANUFACTURING THE SAME

(71) Applicant: IOTMEMORY TECHNOLOGY INC., Taipei City (TW)

(72) Inventors: Der-Tsyr Fan, Taoyuan City (TW); I-Hsin Huang, Taoyuan City (TW); Tzung-Wen Cheng, New Taipei City (TW); Yu-Ming Cheng, Yilan County (TW); Chen-Ming Tsai, Miaoli County (TW)

(21) Appl. No.: 18/382,069

(22) Filed: Oct. 20, 2023

Related U.S. Application Data
(60) Provisional application No. 63/424,139, filed on Nov. 10, 2022.
(60) Provisional application No. 63/469,041, filed on May 25, 2023.

(51) Int. Cl. H01L 29/423; H01L 21/28; H01L 29/66; H01L 29/788; H10B 41/30

(52) U.S. Cl. CPC H01L 29/42328; H01L 29/40114; H01L 29/66825; H01L 29/7883; H10B 41/30

(57) ABSTRACT

A non-volatile memory device includes a memory cell including a substrate, a select gate, a control gate, a planar floating gate, a coupling dielectric layer, an erase gate dielectric layer, and an erase gate. The select gate and the control gate are disposed on the substrate and laterally spaced apart from each other, and the control gate includes a non-vertical surface. The planar floating gate includes a lateral tip laterally spaced apart from the control gate. The coupling dielectric layer includes a first thickness (T1). The erase gate dielectric layer covers the non-vertical surface of the control gate and the lateral tip of the planar floating gate, and includes a second thickness (T2). The erase gate covers the erase gate dielectric layer and the lateral tip of the planar floating gate. The first thickness and the second thickness satisfy the following relation: (T2)<(T1)<2(T2).

### CROSS REFERENCE TO RELATED APPLICATIONS

This application claims the benefit of U.S. Provisional Application No. 63/424,139, filed on Nov. 10, 2022. Further, this application claims the benefit of U.S. Provisional Application No. 63/469,041, filed on May 25, 2023. The contents of these applications are incorporated herein by reference.

### BACKGROUND OF THE INVENTION

### 1. Field of the Invention

The invention relates to a semiconductor device, and more particularly, to a non-volatile memory device and a method for manufacturing the same.

### 2. Description of the Prior Art

Since a non-volatile memory can, for instance, repeatedly perform operations such as storing, reading, and erasing data, and since stored data is not lost after the non-volatile memory is shut down, the non-volatile memory has been extensively applied in personal computers and electronic equipment.

A conventional structure of non-volatile memory has a stack-gate structure, including a tunneling oxide layer, a floating gate, a coupling dielectric layer, and a control gate disposed on a substrate in order. When a programming or erase operation is performed on such a flash memory device, a suitable voltage is respectively applied to the source region, the drain region, and the control gate, such that electrons are injected into a floating gate, or electrons are pulled out from the floating gate.

In the programming and erase operation of the non-volatile memory, a greater gate-coupling ratio (GCR) between the floating gate and the control gate generally means a lower operating voltage is needed for the operation, and the operating speed and the efficiency of the flash memory are significantly increased as a result. However, during programming or erase operations, electrons have to be injected into or pulled out of the floating gate through a tunneling oxide layer disposed under the floating gate, which often causes damages to the structure of the tunneling oxide layer and thus reduces the reliability of the memory device.

In order to increase the reliability of the memory device, an erase gate is adopted and incorporated into to the memory device, which is capable of pulling the electrons from the floating gate by applying a positive voltage to the erase gate. Thus, since the electrons in the floating gate is pulled out through a tunneling oxide layer disposed on the floating gate rather than through the tunneling oxide layer disposed under the floating gate, the reliability of the memory device is further improved.

With an increasing demand for high-efficient memory devices capable of erasing the stored data more efficiently, there is still a need to provide an improved memory device and a method for manufacturing the same.

### SUMMARY OF THE INVENTION

The invention provides a non-volatile memory device and a method for manufacturing a non-volatile memory device. The non-volatile memory device is capable of erasing the stored data more efficiently.

According to some embodiments of the present disclosure, a non-volatile memory device includes at least one memory cell, and the memory cell includes a substrate, a select gate, a control gate, a planar floating gate, a coupling dielectric layer, an erase gate dielectric layer, and an erase gate. The select gate is disposed on the substrate. The control gate is disposed on the substrate and laterally spaced apart from the select gate, and the control gate includes a non-vertical surface. The planar floating gate is disposed between the substrate and the control gate, and the planar floating gate includes a lateral tip laterally spaced apart from the control gate. The coupling dielectric layer disposed between the control gate and the planar floating gate, and the coupling dielectric layer includes a first thickness. The erase gate dielectric layer covers the non-vertical surface of the control gate and the lateral tip of the planar floating gate, and the erase gate dielectric layer includes a second thickness. The erase gate covers the erase gate dielectric layer and the lateral tip of the planar floating gate. In order to create a favored electric field for making electrons tunnel out of the planar floating gate during an erase operation, the first thickness and the second thickness may satisfy the following relation: (T2)<(T1)<2(T2). T1 represents the first thickness of the coupling dielectric layer, and T2 represents the second thickness of the erase gate dielectric layer.

According to some embodiments of the present disclosure, a method for manufacturing a non-volatile memory device includes: providing a substrate; forming a floating gate layer on the substrate; forming a select gate layer on the substrate, where the select gate layer is laterally spaced apart from the floating gate layer; forming a control gate covering a sidewall of the select gate layer and the floating gate layer, where the control gate includes a non-vertical surface; etching the floating gate layer using the control gate as an etch mask to thereby form a planar floating gate, where the planar floating gate includes a lateral tip laterally spaced apart from the control gate; and forming an erase gate covering the non-vertical surface of the control gate and the lateral tip of the planar floating gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of a non-volatile memory device according to some embodiments of the present disclosure.

FIG. 2 is a schematic cross-sectional view of a non-volatile memory device taken along line A-A′ of FIG. 1 according to some embodiments of the present disclosure.

FIG. 3 is a schematic cross-sectional view of a region of a non-volatile memory device of FIG. 2 according to some embodiments of the present disclosure.

FIG. 4 is a schematic cross-sectional view of a non-volatile memory device taken along line B-B′ and line C-C′ of FIG. 1 according to some embodiments of the present disclosure.

FIG. 5 is a schematic cross-sectional view of a non-volatile memory device corresponding to line A-A′ of FIG. 1 according to alternative embodiments of the present disclosure.

FIG. 6A to FIG. 6E are schematic diagrams at various stages of manufacture of a method for manufacturing the non-volatile memory device of FIGS. 1-4 according to some embodiments of the present disclosure.

FIG. 7A to FIG. 7C are schematic cross-sectional views at various stages of manufacture of a method for manufacturing the non-volatile memory device of FIGS. 1 and 5 according to some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

Although the disclosure is described with respect to specific embodiments, the principles of the disclosure, as defined by the claims appended herein, may obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

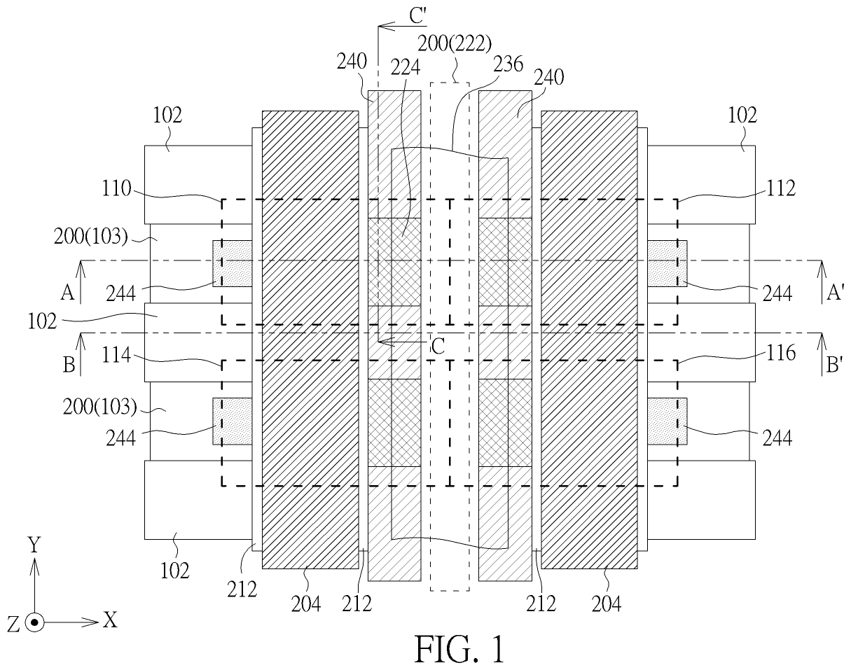

FIG. 1 is a schematic top view of a non-volatile memory device according to some embodiments of the present disclosure. Referring to FIG. 1, a non-volatile memory device 100_1 can be a NOR flash memory device including at least one memory cell, such as four memory cells accommodated in the first, second, third, and fourth memory cell regions 110, 112, 114, and 116, respectively. The structures in the first memory cell region 110 and the second memory cell region 112 have a mirror image of each other, and the structures in the third memory cell region 114 and the fourth memory cell region 116 have a mirror image of each other. According to one embodiment of the present disclosure, the non-volatile memory device 100_1 includes more than four memory cells, and these memory cells can be arranged in an array with numerous rows and columns.

Referring to FIG. 1, the non-volatile memory device includes a substrate 200 and an isolation structure 102. The substrate 200 can be a semiconductor substrate, such as a silicon substrate or silicon-on-insulator (SOI) substrate, but not limited thereto. The isolation structure 102 can be made an insulating material and is used to define active areas 103 of the memory cells.

Each of the memory cells includes a source region 222 and a drain region 244 disposed in the active area 103 defined by the isolation structure 102. The source region 222 and the drain region 244 can be doped regions of the same conductivity type, such as n-type or p-type. The conductivity type of the source region 222 and the drain region 244 is different from the conductivity type of the substrate 200, or different from the conductivity type of a doped well (not shown) used to accommodate the source region 222 and the drain region 244. The source region 222 can be disposed at one end of the active area 103, and the drain region 244 can be arranged at another end of the active area 103. According to some embodiments of the present disclosure, the source region 222 is a continuous region extending along a Y-direction and shared by the memory cells in the same column.

Each memory cell can further include a select gate 206 disposed on the substrate 200 and adjacent to the drain region 244. The select gate 204 can extend along the Y-direction and shared by the memory cells that are located in the same column. The select gate 204 can be made of conductive material such as poly silicon or metal, and select gate 204 can act as a word line configured to turn on/off the channel regions of the memory cells that are disposed underneath the word line. Thus, the channel regions of the memory cells in the same column can be turned on or off concurrently.

A dielectric spacer 212 can be disposed on the sidewalls of the select gate 204 in order to insulate the select gate 204 from other conductive components. The dielectric spacer 212 can be a single-layered, double-layered, or a multi-layered spacer disposed on each sidewall of the select gate 204, but not limited thereto.

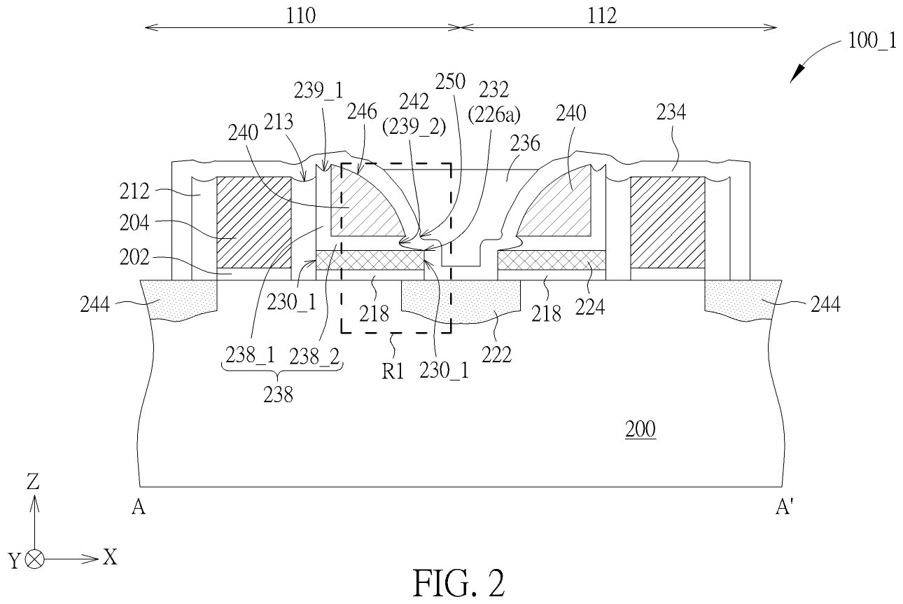

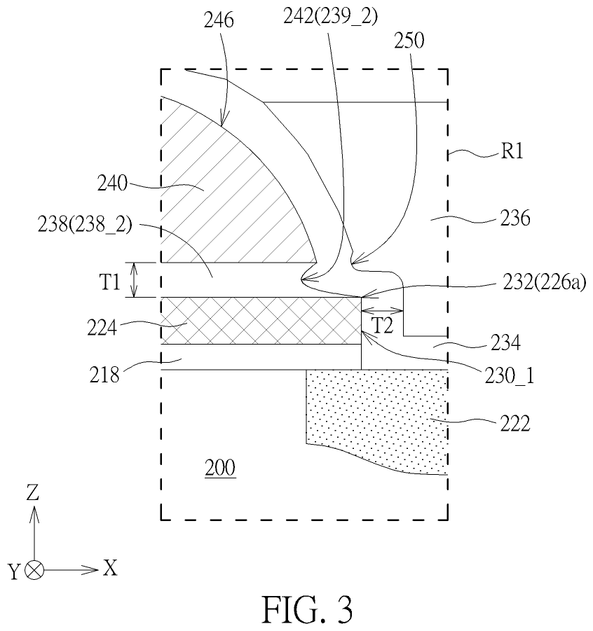

Each memory cell also includes a planar floating gate 224 disposed on the substrate 200 and adjacent to the source region 222. Thus, the planar floating gate 224 is disposed at one side of the select gate 204, and the drain region 244 is disposed at another side of the select gate 204. The floating gates 224 are made of conductive material, such as polysilicon or other semiconductor. The floating gates 224 are spaced apart from each other so that the charges stored in the floating gates 224 could not directly transmitted between the neighboring floating gates 224. Since the floating gates 224 are spaced apart from each other, each the planar floating gate 224 can be programed or erased independently to thereby determine the state of each memory cell, such as state “1” or state “0”. As shown in the following cross-sectional views such as FIG. 2 and FIG. 3, each planar floating gate 224 is a planar floating gate with a substantially flat top surface. The detailed structure of the planar floating gate 224 is described in the description corresponding to FIG. 2 and FIG. 3.

Each memory cell also includes a control gate 240 disposed on the substrate 200 and adjacent to the source region 222. The control gate 240 can extend along the Y-direction and shared by the memory cells that are in the same column. Thus, the floating gates 224 can be covered with the control gate 240 that are in the same column. Besides, the planar floating gate 224 can partially protrude from the control gate 240 towards the boundary between the neighboring memory cell regions in the same row. The control gate 240 can be made of conductive material such as poly silicon or metal, and the control gate 240 is configured to make hot carriers (e.g. electrons) injected from the channel region into the corresponding planar floating gate 224.

The non-volatile memory device 100_1 further includes an erase gate 236 extending along the Y-direction. Besides, the erase gate 236 can be a continuous layer filling up the gap at the boundary between the neighboring memory cell regions in the same row (such as a gap between the two adjacent floating gates 224 in the same row). Therefore, the erase gate 236 can cover at least two floating gates 224 and two control gate 240 in the first memory cell region 110 and the second memory cell region 112. In an erasing operation of the non-volatile memory 100, the erase gate 236 is biased, which causes the electrons stored in the planar floating gate 224 to be pulled out mainly through a lateral tip (not shown) of the planar floating gate 224. The location and arrangement of the lateral tip of the planar floating gate 224 is described in detailed below.

FIG. 2 is a schematic cross-sectional view of a non-volatile memory device taken along line A-A′ of FIG. 1 according to some embodiments of the present disclosure. Referring to FIG. 2, the planar floating gate 224 is the planar floating gate disposed between the substrate 200 and the control gate and 240. The planar floating gate 224 includes a protruding portion 232 exposed from the control gate 240. The planar floating gate 224 also includes a lateral tip 226a corresponding to the upper corner of the protruding portion 232 and laterally spaced apart from the control gate 240. During an erase operation, the electrons stored in the planar floating gate 224 can be pulled out mainly through the lateral tip 226a of planar floating gate 224. Besides, the planar floating gate 224 further includes two opposite first sidewalls 230_1. The first sidewalls 230_1 opposite each other and arranged along the first direction, e.g. X-direction, where one of the first sidewalls 230_1 is connected to the lateral tip 226a of the planar floating gate 224.

The control gate 240 is disposed on the substrate 200 and laterally spaced apart from the select gate 204. The control gate 240 includes a non-vertical surface 246, such as an inclined surface or a curved surface. For example, the non-vertical surface 246 is a convex surface.

The erase gate 236 is a continuous layer extending from the first memory cell region 110 to the second memory cell region 112. The erase gate 236 covers portions of the non-vertical surface 246 of the control gate 240 and the lateral tip 226a of the planar floating gate 224. Since the erase gate 236 partially covers the non-vertical surface 246 of the control gate 240, that portion of the bottom surface of the erase gate 236 is a curved surface.

The erase gate 236 is filled into the gap at the boundary of the first memory cell region 110 and the second memory cell region 112. Because the curved sidewall 239_2 of the end portion 242 of the coupling dielectric layer 238 has the concave surface, a corresponding portion of the erase gate 236 can include a protruding portion 250 extending toward the curved sidewall 239_2 (such as a concave sidewall) of the end portion 242 of the coupling dielectric layer 238. The protruding portion 250 of the erase gate 236 can cover the lateral tip 226a of planar floating gate 224, which causes the erase gate 236 to partially wrap around the lateral tip 226a of the planar floating gate 224. Thus, the electron originally stored in the planar floating gate 224 can be pulled out through the lateral tip 228a of the planar floating gate 224 more effectively.

The erase gate 236 also includes a flat top surface covering the non-vertical surface 246 of the control gate 240, and the erase gate 236 is laterally spaced apart from the select gate 204. Because the height of the erase gate 236 is at most 20% higher than, or even lower than, the height of the select gate 204, the non-volatile memory device 110_1 can be readily integrated with other semiconductor devices, such as MOSFET, in a digital circuit. Thus, the non-volatile memory devices 110_1 and other semiconductor devices in the digital circuit can be manufactured concurrently without significantly adjusting or modifying the process for manufacturing the semiconductor devices.

The non-volatile memory device 100_1 further include a coupling dielectric layer 238 disposed between the control gate 240 and the planar floating gate 224. the coupling dielectric layer 238 is a composite dielectric layer including silicon oxide/silicon nitride/silicon oxide, but not limited thereto.

The coupling dielectric layer 238 is an L-shaped coupling dielectric layer includes a vertical portion 238_1 and a horizontal portion 238_2. The vertical portion 238_1 of the coupling dielectric layer 238 is disposed between the control gate 240 and the vertical portion 224_1 of the planar floating gate 224. The vertical portion 238_1 of the coupling dielectric layer 238 includes a top surface 239_1 with a curved profile, but not limited thereto. The horizontal portion 238_2 is disposed between the control gate 240 and the horizontal portion 224_2 of the planar floating gate 224, where an end portion 242 of the horizontal portion 238_2 of the coupling dielectric layer 238 extends from below the control gate 240 and is exposed from the control gate 240. The end portion 242 of the horizontal portion 238_2 of the coupling dielectric layer 238 includes a curved sidewall 239_2 exposed from the control gate 240. The curved sidewall 239_2 is a concave surface in direct contact with an erase gate dielectric layer 234.

The non-volatile memory device 100_1 further include an erase gate dielectric layer 234 disposed between the erase gate 236 and planar floating gate 224, and between the erase gate 236 and control gate 240. The erase gate dielectric layer 234 can be made of dielectric layer which allows electrons originally stored in the planar floating gate 224 to pass through it by Fowler-Nordheim (FN) tunneling mechanism. In some embodiments, the erase gate dielectric layer 234 is a continuous layer extending from the first memory cell region 110 and the second memory cell region 112. Besides, top surface of the select gate 204 and the top tip of the control gate 240 can be covered with the erase gate dielectric layer 234. During a programming operation, hot electrons are allowed to pass through the floating gate dielectric layer 218 and accumulate in the planar floating gate 224.

The dielectric spacer 212 is disposed one the sidewalls of the select gate 204. In some embodiments of the present disclosure, the dielectric spacer 212 includes a concave top surface 213.

The non-volatile memory device 100_1 further include a select gate dielectric layer 202 disposed between substrate 200 and the select gate 204. Based on different requirements, the composition of the select gate dielectric layer 202 can be the same as or different from the composition of the floating gate dielectric layer 218.

FIG. 3 is a schematic cross-sectional view of a region of a non-volatile memory device of FIG. 2 according to some embodiments of the present disclosure. The structure shown in FIG. 3 corresponds to a region R1 of the structure shown in FIG. 2. Referring to FIG. 3, the lateral tip 226a of the planar floating gate 224 can be covered with a thin layer of the coupling dielectric layer 238. For example, the thickness of the coupling dielectric layer 238 covering the lateral tip 226a of the planar floating gate 224 can be on the order of 5 Angstroms to 30 Angstroms, but not limited thereto. In order to erase the charges stored in the planar floating gate 224 more efficiently, the lateral tip 226a may not be covered with any coupling dielectric layer 238. Thus, the lateral tip 226a is in direct contact with the erase gate dielectric layer 234.

The horizontal portion 238_2 of the coupling dielectric layer 238 includes a curved sidewall 239_2 such as a concave sidewall. The profile of the curved sidewall 239_2 can affect the profile of the corresponding portion of the erase gate 236. For example, when there is an increase in the curvature of the curved sidewall 239_2, the protruding portion 250 of the erase gate 236 can protrude more towards the curved sidewall 239_2 of the coupling dielectric layer 238. Thus, not only the lateral tip 226a but also the region of the planar floating gate 224 that is adjacent to the lateral tip 226a is covered with the protruding portion 250 of the erase gate 236. In this way, the erasing efficient can be further improved.

The erase gate dielectric layer 234 substantially conformally covers the control gate 240, the curved sidewall 239_2 of the coupling dielectric layer 238, and the first sidewall 230_1 of the planar floating gate 224. Since portions of the curved sidewall 239_2 of the coupling dielectric layer 238 is covered with the control gate 240, the portion of the erase gate dielectric layer 234 that is in direct contact with the coupling dielectric layer 238 can be disposed between the control gate 240 and the planar floating gate 224.

In order to create a favored electric field for making electrons tunnel out of the planar floating gate 224 during an erase operation, the curvature and profile of the protruding portion 250 of the erase gate 236 can be properly controlled. The relationship between the thickness (also called first thickness) T1 of the coupling dielectric layer 238 and the thickness (also called second thickness) T2 of the erase gate dielectric layer 234 satisfies the following expression:

(T2)<(T1)<2(T2)

where T1 represents the average thickness of the coupling dielectric layer 238 that is covered with the control gate 240, and T2 represents the average thickness of the erase gate dielectric layer 234 that is on the first sidewall 230_1 of the planar floating gate 224.

When the first thickness T1 of the coupling dielectric layer 238 is less than the second thickness T2 of the erase gate dielectric layer 234, the corresponding erase gate dielectric layer 234 is less likely filled into the space between the control gate 240 and the planar floating gate 224. Therefore, the protruding portion 250 of the erase gate 236 may protrude less, and thus the lateral tip 226a of the planar floating gate 224 is no longer covered with the protruding portion 250. Thus, the ease efficiency is reduced.

In contrast, when the first thickness T1 of the coupling dielectric layer 238 is greater than twice the second thickness T2 of the erase gate dielectric layer 234, the corresponding erase gate dielectric layer 234 is more likely filled into the space between the control gate 240 and the planar floating gate 224. As a result, the end of the protruding portion 250 of the erase gate 236 becomes a pointed end. During the operation of the non-volatile memory device 100_1, the electron may be ejected from the pointed end of the protruding portion 250, which causes the accumulation of positive charges in the protruding portion 250 and thus negatively affects electrical characteristic of the non-volatile memory device 100_1.

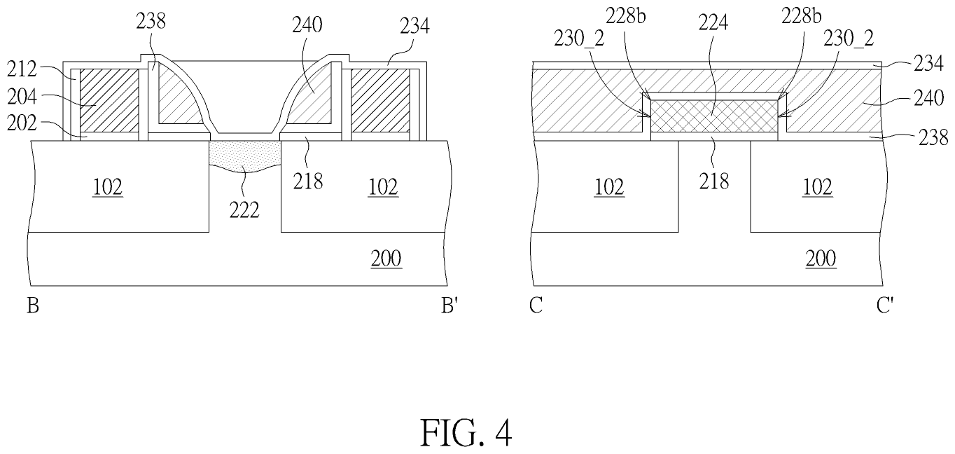

FIG. 4 is a schematic cross-sectional view of a non-volatile memory device taken along line B-B′ and line C-C′ of FIG. 1 according to some embodiments of the present disclosure. Referring to view BB′ of FIG. 4, the control gate 240 and the erase gate 236 can be disposed on the isolation structure 102, and the control gate 240 can be disposed between the erase gate 236 and the isolation structure 102. Besides, the isolation structure 102 shown in FIG. 4 is not covered with the planar floating gate 224. The coupling dielectric layer 238 is an L-shaped layer disposed on the isolation structure 102.

Referring to view CC′ of FIG. 4, the planar floating gate 224 includes two second sidewalls 230_2 which are opposite each other and arranged along a second direction different from the first direction, e.g. the Y-direction. The control gate 240 extends along the second direction and covers the second sidewalls 230_2 of the planar floating gate 224. Besides, the second sidewalls 230 can also be covered with the coupling dielectric layer 238. The control gate 240 shown in view CC′ is not covered with any erase gate (not shown).

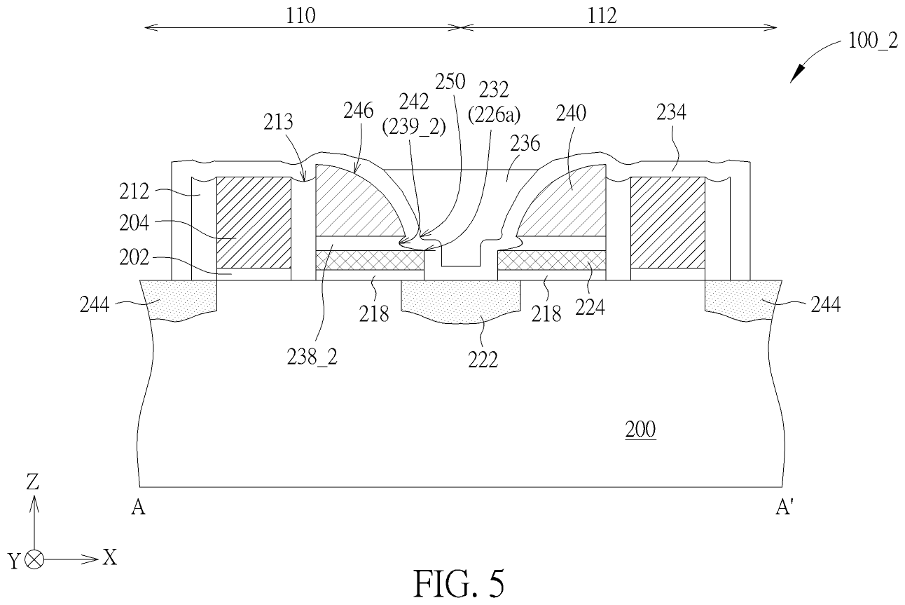

FIG. 5 is a schematic cross-sectional view of a non-volatile memory device corresponding to line A-A′ of FIG. 1 according to alternative embodiments of the present disclosure. Referring to FIG. 5, the non-volatile memory device 100_2 shown in FIG. 3 is analogous to the non-volatile memory device 100_1 shown in FIG. 2, the main difference is that the coupling dielectric layer 238 has only the horizontal portion 238_2 and the vertical portion shown in FIG. 2 is omitted. Thus, the entire top surface of the coupling dielectric layer 238 can be covered with the control gate 240. Besides, the end portion 242 of the coupling dielectric layer 238 still includes the curved sidewall 239_2, and a portion of the curved sidewall 239_2 protrudes from the control gate 240.

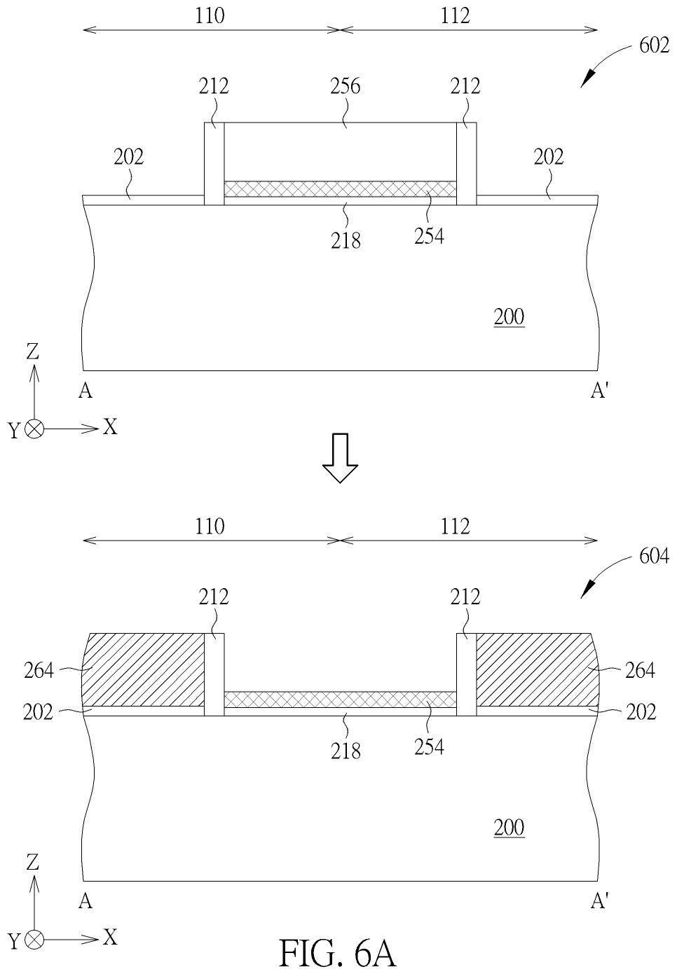

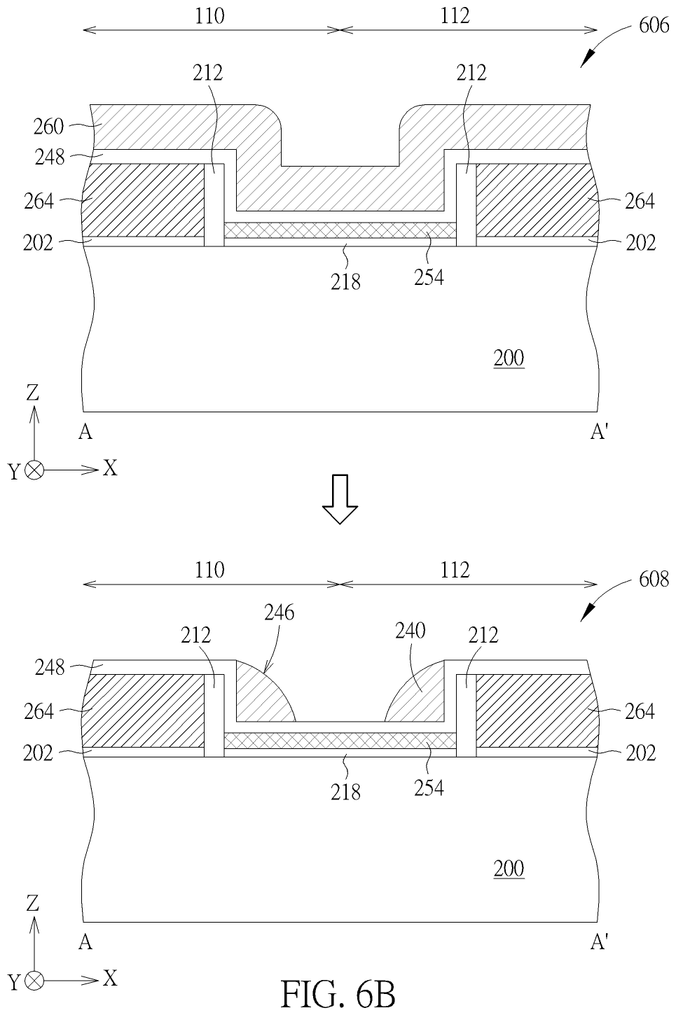

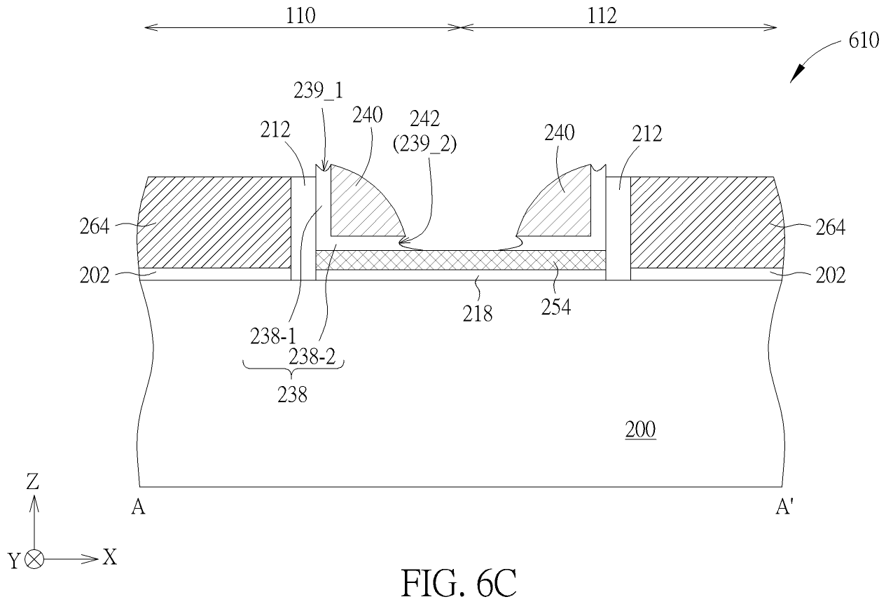

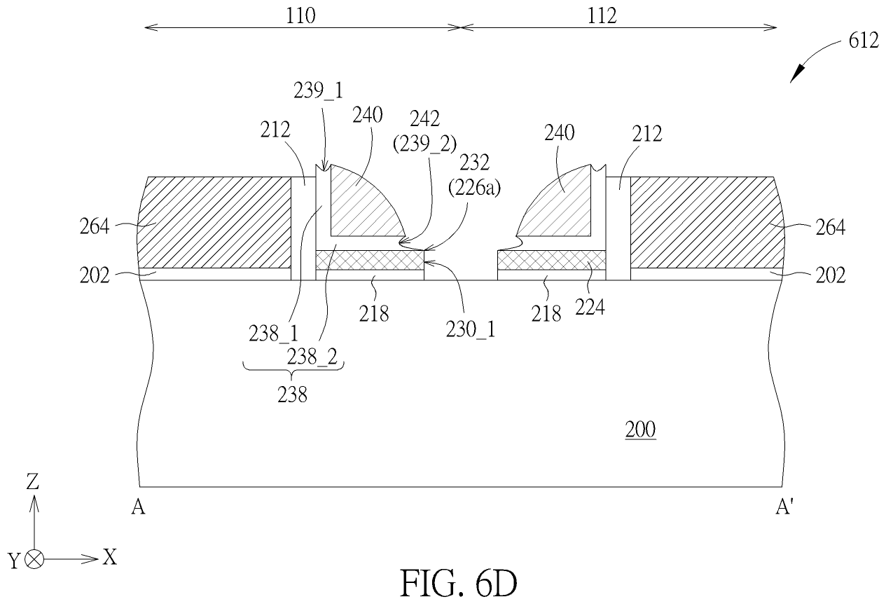

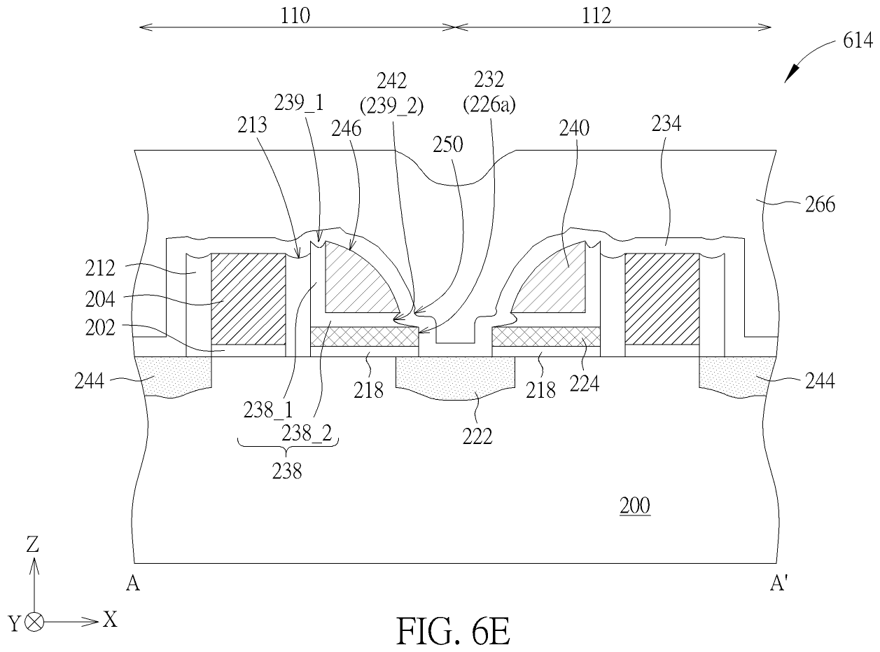

FIG. 6A to FIG. 6E are schematic diagrams at various stages of manufacture of a method for manufacturing the non-volatile memory device of FIGS. 1-4 according to some embodiments of the present disclosure.

Referring to FIG. 6A, in step 602, a substrate 200 is provided. Then, a floating gate dielectric layer 218, a floating gate layer 254, and an etch mask 256, which are stacked in sequence, are disposed on the substrate 200. Afterwards, the floating gate dielectric layer 218 and the floating gate layer 254 can be formed by deposition and etching processes. During the etching process, the pattern of the etch mask 256 can be transferred to the floating gate dielectric layer 218 and the floating gate layer 254. Besides, after the etching process, the floating gate dielectric layer 218 and the floating gate layer 254 can extend along a Y-direction (also called a second direction) in a top view.

Then, a dielectric spacer 212 is formed on the sidewall of the floating gate layer 254, the floating gate dielectric layer 218, and the etch mask 256. A select gate dielectric layer 202 is formed on the substrate 200 at two sides of the floating gate dielectric layer 218.

Then, in step 604, the select gate layer 264 is formed on the substrate 200 at two sides of the floating gate dielectric layer 218. The select gate layer 264 is laterally spaced apart from the floating gate layer 254. In the following processes, the select gate layer 264 can be further patterned or modified to act as a select gate of a non-volatile memory device. The method of forming the select gate layer 264 may include the following steps. For example, a conductive layer (not shown) is deposited on the substrate 200 to cover the etch mask 256. Then, a planarization process is performed on the conductive layer to planarize the top surface of the conductive layer until the top surface of the etch mask 256 is exposed. After the formation of the select gate layer 264, the etch mask 256 can be removed to expose the top surface of the floating gate layer 254. Then, photolithography and etching processes are performed to etch the floating gate layer 254 and the floating gate dielectric layer 218. As a result, the floating gate layer 254 and the floating gate dielectric layer 218 can be patterned to form a plurality of stripe-shaped structures (not shown) that are disposed along the Y-direction and separated from each other in a top view. Each of the stripe-shaped structures can extend along the X-direction, and in both the first memory cell region 110 and the second memory cell region 112.

Referring to FIG. 6B, in step 606, a coupling dielectric layer 248 is formed on the substrate 200 to conformally cover the select gate layer 264 and the floating gate layer 254. Since the floating gate layer 254 is stripe-shaped as viewed from a top-down perspective, the coupling dielectric layer 248 covers not only the top surface of the floating gate layer 254 but also the sidewalls (not shown) of the floating gate layer 254. The coupling dielectric layer 248 can be a composite dielectric layer including silicon oxide/silicon nitride/silicon oxide, but not limited thereto.

Then, a control gate layer 240 is disposed on the coupling dielectric layer 248. The thickness of the control gate layer 240 can be properly controlled so that the control gate layer 240 can conform to the shape of the underlying structure. The control gate layer 240 can be made of conductive material such as poly silicon or metal, but not limited thereto.

Then, in step 608, the control gate layer 240 is then etched by an anisotropic etching process to thereby form the control gate 240 on the sidewall of the select gate layer 264 and on the top surface of the floating gate layer 254. The control gate 240 is a self-aligned structure with a non-vertical surface 246, and thus there is no need to use the photolithography process. After the formation of the control gate 240, the control gates 240 respectively in the first memory cell region 110 and the second memory cell region 112 can be laterally separated from each other in the X-direction. Besides, after the formation of the control gate 240, the portion of the coupling dielectric layer 248 that disposed over the select gate layer 264 can be exposed from the control gate 240.

Referring to FIG. 6C, in step 610, by using the control gate layer 240 as an etch mask, an anisotropic etching process is performed on the coupling dielectric layer 248 to thereby form a coupling dielectric layer 238 which is an L-shaped structure including a vertical portion 238_1 and a horizontal portion 238_2. The vertical portion 238_1 is disposed between the control gate 240 and the select gate layer 264. The horizontal portion 238_2 is disposed between the control gate 240 and the substrate 200. By properly controlling the etching recipe and types or ratios of etchants, the top surface 239_1 of the vertical portion 238_1 can be a flat or concave surface which is lower than the top tip of the control gate 240. Besides, the horizontal portion 238_2 of the coupling dielectric layer 238 includes an end portion 242 extending from below the control gate 240 and is exposed from the control gate 240. The end portion 242 of the horizontal portion 238_2 of the coupling dielectric layer 238 includes a curved sidewall 239_2 extending and exposed from the control gate 240. After the formation of the coupling dielectric layer 238 including the vertical portion 238_1 and the horizontal portion 238_2, the portion of the floating gate layer 254 that is at the boundary between the first memory cell region 110 and the second memory cell region 112 can be exposed.

Referring to FIG. 6D, in step 612, the floating gate layer 254 is etched using the control gate 240 and the coupling dielectric layer 238 as an etch mask to thereby form the planar floating gate 224. The planar floating gate 224 is a planar structure includes a lateral tip 226a laterally and vertically spaced apart from the control gate 240. By using the control gate 240 and the coupling dielectric layer 238 as the etch masks, there is no need to perform additional photolithography process to define the shape of the planar floating gate 224. Furthermore, during the formation of the planar floating gate 224, portions of the control gate 240 can be etched concurrently and the height of the control gate 240 may be slightly reduced. Even if the size of the control gate 240 is reduced during the etching process, the size of coupling dielectric layer 238 is not reduced much since the composition of the coupling dielectric layer 238 is different from the composition of the planar floating gate 224. After the formation of the planar floating gate 224, the floating gate dielectric layer 218 can also be etched to expose the substrate 200 at the boundary between the first memory cell region 110 and the second memory cell region 112.

Referring to FIG. 6E, in step 614, the select gate layer 264 can be patterned to form select gates 204. At least one drain region 244, such as two drain regions 244, may be formed at sides of the select gates 204. The drain regions 244 are disposed in the first memory cell region 110 and the second memory cell region 112 respectively, which can be electrically coupled to each other through vias or contacts in the subsequent manufacturing processes. Besides, a source region 222 can be concurrently formed in the substrate 200 between the control gates 220.

The forming method of the drain region 244 and the source region includes, for instance, performing an ion implantation process. The implanted dopant can be an n-type or p-type dopant as decided according to the design of the device. The dopants and the doping concentrations of the source region 222 and the drain region 244 can be the same and can also be different.

An erase gate dielectric layer 234 is then conformally formed on the select gate 204, the planar floating gate 224, and the control gate 240. A portion of the erase gate dielectric layer 234 can fill into the gap between the control gate 240 and the planar floating gate 224.

Then, an erase gate layer 266 is deposited to cover the control gate 240 and fills into the gap at the boundary between the first memory cell 110 and the second memory cell 112. The erase gate layer 266 covers not only the non-vertical surface 246 of the control gate 240 but also the lateral tip 226a of the planar floating gate 224.

Afterwards, a planarization process may be performed on the erase gate layer 266 to form a erase gate as shown in FIG. 2. Besides, other components can be manufactured by performing suitable manufacturing processes so as to obtain a non-volatile memory device similar to the structures shown in FIGS. 1-4.

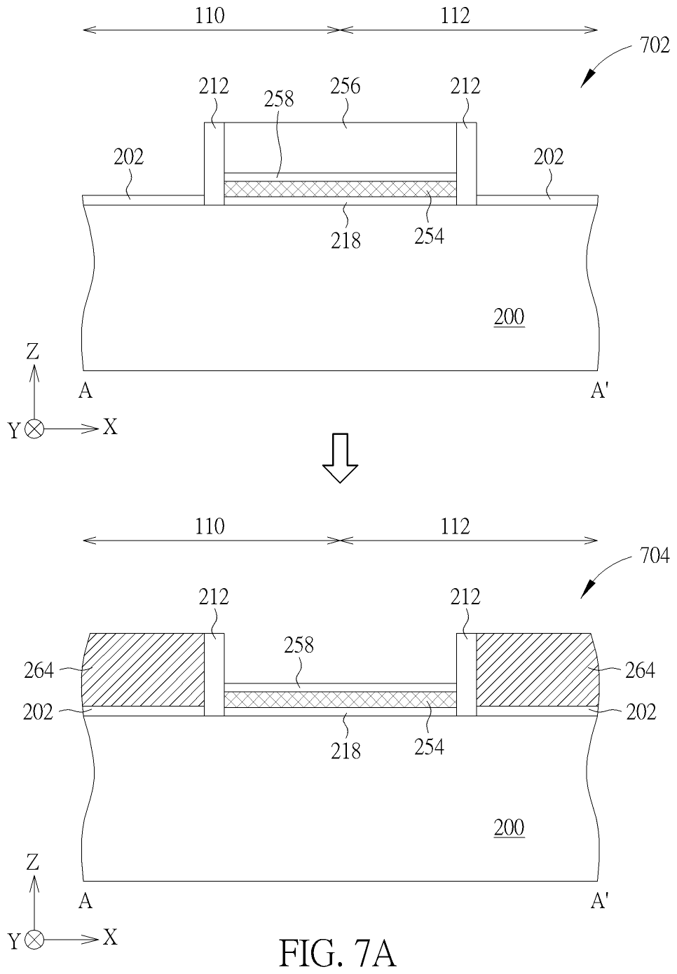

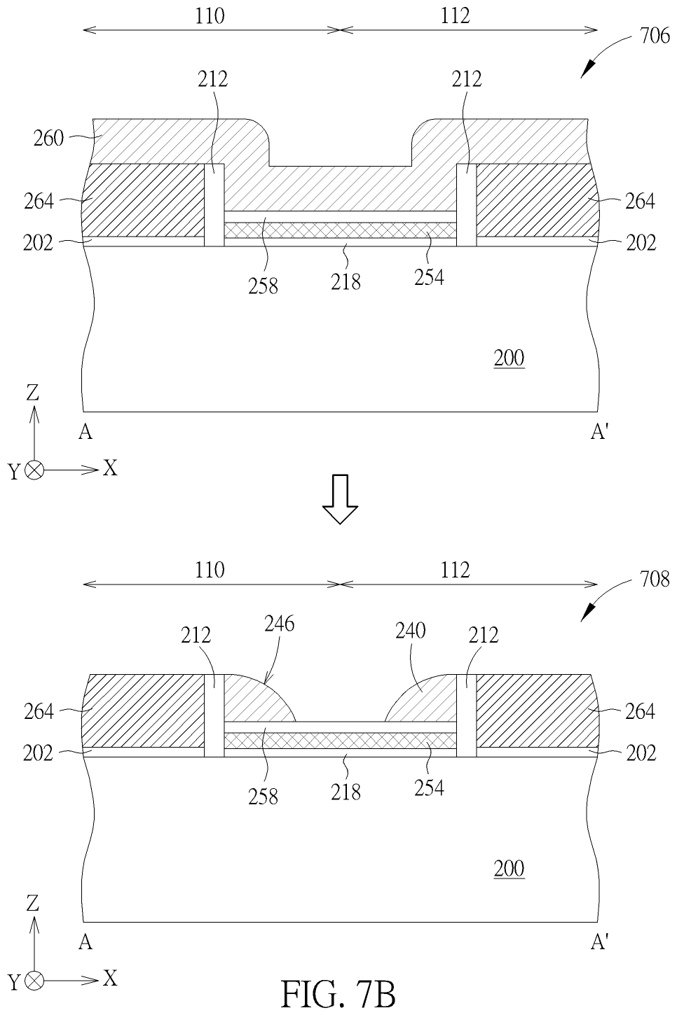

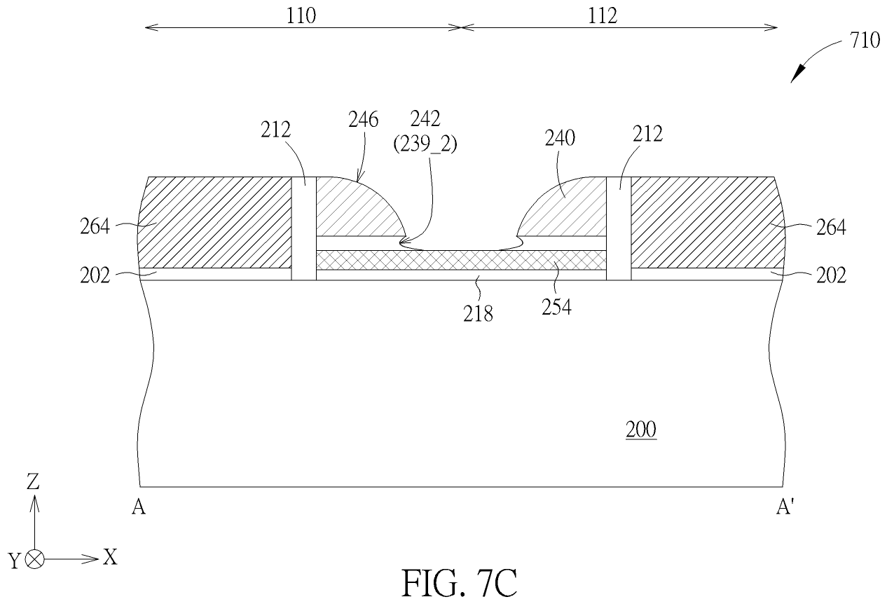

FIG. 7A to FIG. 7C are schematic cross-sectional views at various stages of manufacture of a method for manufacturing the non-volatile memory device of FIGS. 1 and 5 according to some embodiments of the present disclosure. In FIG. 7A to FIG. 7C, the structures correspond to the line A-A′ of FIG. 1. Besides, since the manufacturing processes of the embodiments shown in FIG. 7A to FIG. 7C are similar to the manufacturing processes of the embodiments shown in FIG. 6A to FIG. 6E, only the main differences between the embodiments are described for the sake of brevity.

Referring to FIG. 7A, in step 702, a floating gate dielectric layer 218, a floating gate layer 254, a coupling dielectric layer 258, and an etch mask 256, which are stacked in sequence, are disposed on the substrate 200. The floating gate dielectric layer 218, the floating gate layer 254, and the coupling dielectric layer 258 can be formed by using a deposition and etching process. During the etching process, the pattern of the etch mask 256 can be transferred to the floating gate dielectric layer 218, the floating gate layer 254, and the coupling dielectric layer 258. The floating gate dielectric layer 218, the floating gate layer 254, and the coupling dielectric layer 258 can extend along the Y-direction (also called a second direction) in a top view. A dielectric spacer 212 is formed on the sidewall of the floating gate layer 254, the floating gate dielectric layer 218, and the etch mask 256. A select gate dielectric layer 202 is disposed on the substrate 200 at two sides of the floating gate dielectric layer 218.

Then, in step 704, the select gate layer 264 is formed on the substrate 200 at two sides of the floating gate dielectric layer 218. The select gate layer 264 is laterally spaced apart from the floating gate layer 254 and the coupling dielectric layer 258. After the formation of the select gate layer 264, the etch mask 256 can be removed to expose the top surface of the coupling dielectric layer 258.

Then, after step 704, a photolithography and etching process are performed to etch the floating gate layer 254, the floating gate dielectric layer 218, and the coupling dielectric layer 258. As a result, the floating gate layer 254, the floating gate dielectric layer 218, and the coupling dielectric layer 258 can be patterned by the etching process to thereby form a plurality of stripe-shaped structures (not shown) that are separated from each other as viewed from a top-down perspective. Each of the stripe-shaped structures can extend along the X-direction, and at least in the first memory cell region 110 and the second memory cell region 112.

Referring to FIG. 7B, in step 706, a control gate layer 240 is disposed on the coupling dielectric layer 258. The thickness of the control gate layer 240 can be properly controlled so that the control gate layer 240 can conform to the shape of the underlying structure. Since the floating gate layer 254 is stripe-shaped as viewed from a top-down perspective, the control gate layer 240 covers not only the top surface of the floating gate layer 254 but also the sidewalls (not shown) of the floating gate layer 254.

Then, in step 708, the control gate layer 240 is then etched by an anisotropic etching process to thereby form the control gate 240 on the sidewall of the select gate layer 264 and on the top surface of the coupling gate layer 284. The control gate 240 is a self-aligned structure with a non-vertical surface 246, and thus there is no need to use the photolithography process. After the formation of the control gate 240, the control gates 240 respectively in the first memory cell region 110 and the second memory cell region 112 can be laterally separated from each other in the X-direction.

Referring to FIG. 7C, in step 710, by using the control gate layer 240 as an etch mask, an anisotropic etching process is performed on the coupling dielectric layer 248 to thereby form a coupling dielectric layer 238 which is a planar structure. The coupling dielectric layer 238 includes an end portion 242 extending from below the control gate 240 and is exposed from the control gate 240. The end portion 242 of the coupling dielectric layer 238 includes a curved sidewall 239_2 extending and exposed from the control gate 240. After the formation of the coupling dielectric layer 238 including the vertical portion 238_1 and the horizontal portion 238_2, the portion of the floating gate layer 254 that is at the boundary between the first memory cell region 110 and the second memory cell region 112 can be exposed.

Afterwards, the manufacturing processes similar to those described in FIGS. 6D to 6E and other manufacturing processes can be performed to obtain a non-volatile memory device similar to the structure shown in FIGS. 1 and 5.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A non-volatile memory device, comprising at least one memory cell, wherein the at least one memory cell comprises:
a substrate;
a select gate disposed on the substrate;
a control gate disposed on the substrate and laterally spaced apart from the select gate, wherein the control gate comprises a non-vertical surface;
a planar floating gate disposed between the substrate and the control gate, wherein the planar floating gate comprises a lateral tip laterally spaced apart from the control gate;
a coupling dielectric layer disposed between the control gate and the planar floating gate, wherein the coupling dielectric layer comprises a first thickness;
an erase gate dielectric layer covering the non-vertical surface of the control gate and the lateral tip of the planar floating gate, wherein the erase gate dielectric layer comprises a second thickness; and
an erase gate covering the erase gate dielectric layer and the lateral tip of the planar floating gate,
wherein the first thickness and the second thickness satisfy the following relation:
(T2)<(T1)<2(T2)
wherein T1 represents the first thickness of the coupling dielectric layer, and T2 represents the second thickness of the erase gate dielectric layer.

2. The non-volatile memory device of claim 1, wherein the non-vertical surface of the control gate comprises an inclined surface or a curved surface.

3. The non-volatile memory device of claim 1, wherein the planar floating gate further comprises:
two first sidewalls opposite each other and arranged along a first direction, wherein one of the first sidewalls is connected to the lateral tip; and
two second sidewalls opposite each other and arranged along a second direction different from the first direction,
wherein the control gate extends along the second direction and covers the two second sidewalls of the planar floating gate.

4. The non-volatile memory device of claim 3, wherein the coupling dielectric layer extends along the second direction and covers the two second sidewalls of the planar floating gate.

5. The non-volatile memory device of claim 1, wherein the coupling dielectric layer comprises:
a vertical portion disposed between the control gate and the select gate; and
a horizontal portion disposed between the control gate and the planar floating gate, wherein the horizontal portion of the coupling dielectric layer comprises a curved sidewall.

6. The non-volatile memory device of claim 5, wherein the vertical portion of the coupling dielectric layer comprises a curved top surface.

7. The non-volatile memory device of claim 1, wherein the coupling dielectric layer comprises a curved sidewall covered with the control gate.

8. The non-volatile memory device of claim 7, wherein a portion of the erase gate dielectric layer is disposed between the control gate and the planar floating gate.

9. The non-volatile memory device of claim 7, wherein the erase gate comprises a protruding portion extending toward the curved sidewall of the coupling dielectric layer.

10. The non-volatile memory device of claim 1, wherein the erase gate comprises a flat top surface covering the non-vertical surface of the control gate.

11. The non-volatile memory device of claim 1, wherein the erase gate is laterally spaced apart from the select gate.

12. The non-volatile memory device of claim 1, wherein the at least one memory cell comprises a first memory cell and a second memory cell, each of the first memory cell and the second memory cell comprising the select gate, the floating gate and the control gate, the non-volatile memory device further comprises a source region shared by the first memory cell and the second memory cell, and the source region is covered with the erase gate.

13. The non-volatile memory device of claim 10, wherein the first memory cell and the second memory cell have a mirror image of each other.

14. The non-volatile memory device of claim 10, wherein the erase gate is filled into a gap between the control gates of the first memory cell and the second memory cell.

15. A method for manufacturing a non-volatile memory device, comprising:
providing a substrate;
forming a floating gate layer on the substrate;
forming a select gate layer on the substrate, wherein the select gate layer is laterally spaced apart from the floating gate layer;
forming a control gate covering a sidewall of the select gate layer and the floating gate layer, wherein the control gate comprises a non-vertical surface;
etching the floating gate layer using the control gate as an etch mask to thereby form a planar floating gate, wherein the planar floating gate comprises a lateral tip laterally spaced apart from the control gate; and
forming an erase gate covering the non-vertical surface of the control gate and the lateral tip of the planar floating gate.

16. The method for manufacturing a non-volatile memory device of claim 15, further comprising:
forming a coupling dielectric layer on the floating gate layer before forming the control gate; and
etching the coupling dielectric layer using the control gate as the etch mask.

17. The method for manufacturing a non-volatile memory device of claim 16, after etching the coupling dielectric layer, further comprising:
etching the floating gate layer using the coupling dielectric layer as a further etch mask.

18. The method for manufacturing a non-volatile memory device of claim 17, after etching the floating gate layer, further comprising:
etching a sidewall of the coupling dielectric layer to form a curved sidewall covered with the control gate.

19. The method for manufacturing a non-volatile memory device of claim 18, after etching the sidewall of the coupling dielectric layer, further comprising:
forming an erase gate dielectric layer on the planar floating gate, wherein a portion of the erase gate dielectric layer is covered with the control gate.

20. The method for manufacturing a non-volatile memory device of claim 16, wherein, before forming a control gate, the coupling dielectric layer further covers a top surface of the select gate layer.

21. The method for manufacturing a non-volatile memory device of claim 20, wherein, in forming the floating gate, the coupling dielectric layer comprises:
a vertical portion disposed between the control gate and the select gate layer; and
a horizontal portion disposed between the control gate and the substrate, wherein a portion of the horizontal portion of the coupling dielectric layer extends from below the control gate and is exposed from the control gate.

22. The non-volatile memory device of claim 21, wherein, in forming the floating gate, the horizontal portion of the coupling dielectric layer comprises a non-vertical sidewall exposed from the control gate.

23. The method for manufacturing a non-volatile memory device of claim 16, wherein forming the coupling dielectric layer is before forming the select gate layer.
